(19) United States
(12) Patent Application Publication
(10) Pub. No.: US 2025/0261324 A1
(43) Pub. Date: Aug. 14, 2025

(54) ADAPTABLE CLIP DESIGN FOR PRINTED CIRCUIT BOARD/PRINTED CIRCUIT BOARD ASSEMBLY LOCKING

(71) Applicant: Enphase Energy, Inc., Petaluma, CA (US)

(72) Inventors: Raidon Lawrence PINTO, Bangalore (IN); Nalla RAMU, Bangalore (IN); Nayan Kumar SINGH, Bangalore (IN)

(21) Appl. No.: 19/044,837

(22) Filed: Feb. 4, 2025

(30) Foreign Application Priority Data
Feb. 8, 2024 (IN) 202411008491

(51) Int. Cl. H05K 7/14

(52) U.S. Cl. CPC H05K 7/1405

(57) ABSTRACT

An apparatus for securing a board to an enclosure is provided herein. For example, an adaptable clip is operably coupled to a lid of the enclosure and configured to move from an unflexed configuration for receiving the board to a flexed configuration for securing the board to the enclosure.

### CROSS-REFERENCE TO RELATED APPLICATIONS

The present application claims the benefit of and priority to Indian Provisional Application No. 202411008491, filed on Feb. 8, 2024, the entire contents of which is incorporated herein by reference.

### BACKGROUND

### 1. Field of the Disclosure

Embodiments of the present disclosure generally relate to printed circuit board assemblies and, for example, to adaptable clip designs for printed circuit board assembly (PCBA) locking.

### 2. Description of the Related Art

Conventional power conversion systems are known and can comprise a solar system that comprises one or more gateways that communicate via a wired and/or a wireless connection with one or more components (e.g., photovoltaics that can be coupled in a one-to-one correspondence to one or more microinverters, storage systems, main panels, etc.). The one or more gateways, photovoltaics, one or more microinverters, storage systems, main panels, etc. can comprise a PCB/PCBA.

During assembly, the PCB/PCBA can be connected to an enclosure of the components of the solar system using one or more connection methods. For example, sometimes the PCB/PCBA can be snapped to one or more components in the enclosure of a component (e.g., a gateway). During snapping of the PCB/PCBA in the enclosure, however, due to the PCB/PCBA thickness variations and part tolerances, there is a high probability that the PCB/PCBA will either be loosely held in place or might not snap altogether to the enclosure. Having a PCB/PCBA that is loosely held in place may contribute to an end user feeling that the end product is not robust, e.g., a PCB/PCBA that easily shakes around in the enclosure. Additionally, when the PCB/PCBA is not properly secured to the enclosure, there is a likelihood that the PCB/PCBA will slip from the original position of the PCB/PCBA, which may prevent a user from being able to access the available ports and connections on the PCB/PCBA. Moreover, snap-fit designs need numerous iterations to fine tune the tolerances, as the snap-fit designs will not accommodate the PCB/PCBA thickness variations and part tolerances. Further, using boss (screws)/standoff adds to cost and slows down an assembly process of the enclosure, and there is a likelihood that inadequate torque can crack the PCB/PCBA or again hold the PCB/PCBA loosely to the enclosure. The boss (screws)/standoff, which are, typically, made of metal, can also cause clearance creepage issues.

Therefore, described herein are improved adaptable clip designs for PCBA locking.

### SUMMARY

In accordance with some aspects of the present disclosure, there is provided an apparatus for securing a board to an enclosure. The apparatus can comprise an adaptable clip that is operably coupled to a lid of the enclosure and can be configured to move from an unflexed configuration for receiving the board to a flexed configuration for securing the board to the enclosure.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is partial diagram of an enclosure configured for use with one or more components of the system for power conversion of FIG. 1 and comprising a clip configured to secure a PCB/PCBA to the enclosure, in accordance with at least some embodiments of the present disclosure; and

FIG. 3 is the indicated area of detail 3 of FIG. 2 with some parts removed for clarity and with the clip shown prior to and after installation of the PCB/PCBA, in accordance with at least some embodiments of the present disclosure.

### DETAILED DESCRIPTION

Printed circuit board (PCB) and printed circuit board assembly (PCBA) are both terms used in the electronics industry. The main difference between these two terms is that PCB, typically, refers to a blank circuit board, while PCBA, typically, refers to a board that contains all of the necessary electronic components for the board to function as needed. The methods and apparatus described herein are configured for use with both the PCB and the PCBA, and, as such, these terms will be used herein interchangeably, and, in most cases, simply referred to as a board.

In accordance with the present disclosure, described herein are improved adaptable clip designs for board locking. For example, apparatus for securing a board to an enclosure can comprise an adaptable clip that is operably coupled to a lid of the enclosure and configured to move from an unflexed configuration for receiving the board to a flexed configuration for securing the board to the enclosure. The apparatus described herein provide a simple, cost effective method for firmly securing a board to an enclosure. Accordingly, the occurrence of a user not being able to access the available ports and connections on the board is greatly reduced, if not eliminated. Moreover, the apparatus described herein accommodate many board thickness variations and part tolerances. Thus, the need for numerous iterations to fine tune the tolerances of a board is obviated. Further, as there is no need to use boss (screws)/standoff, cost of assembly of the enclosure is reduced, an assembly process of the enclosure is sped up, and the likelihood that inadequate torque cracks the board and clearance creepage issues are greatly reduced, if not eliminated.

The methods and apparatus described herein can be used with both PCB/PCBA (which can be single-layer, double-layer, multiple-layer, etc.) that can be configured for a plethora of uses/functions in the electronics industry, e.g., TVs, radios, printers, calculators, appliances, lighting systems, medical imaging systems, pacemakers, energy management systems, engine management systems, industrial controls, telecom towers, data storage equipment, satellite systems, etc.). For illustrative purposes, the boards described herein are described for use with one or more components of an energy management system.

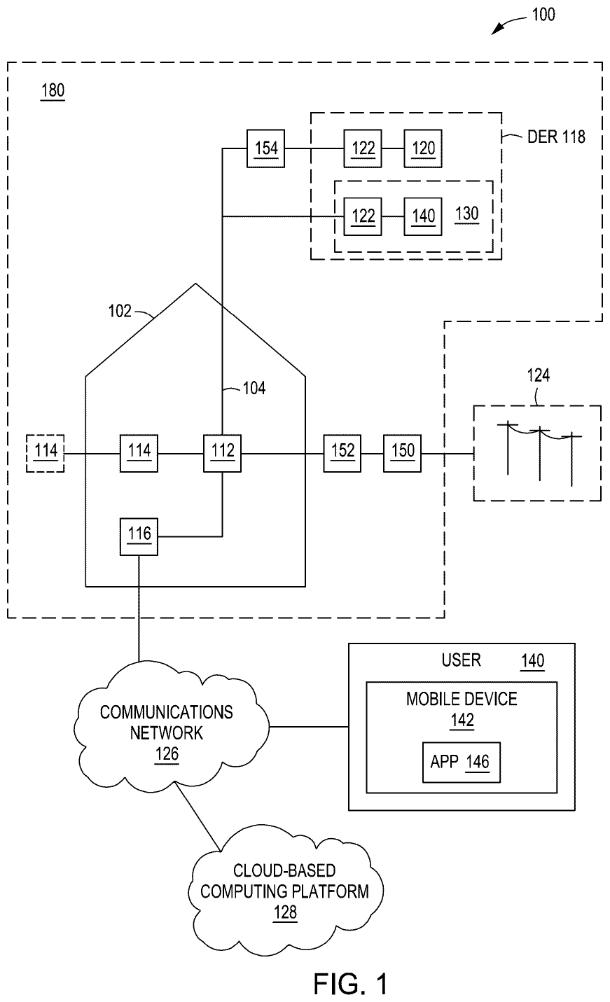

For example, FIG. 1 is a block diagram of an energy management system (e.g., power conversion system, system 100) in accordance with one or more embodiments of the present disclosure. The diagram of FIG. 1 only portrays one variation of the myriad of possible system configurations. The present disclosure can function in a variety of environments and systems.

The system 100 comprises a structure 102 (e.g., a user's structure), such as a residential home, commercial building, or separate mounting structure, having an associated DER 118 (distributed energy resource). The DER 118 is situated external to the structure 102. For example, the DER 118 may be located on the roof of the structure 102 or can be part of a solar farm. Alternatively, the DER 118 can be situated internal to the structure 102. For example, when the DER 118 is a permanent residential battery energy storage system, the DER 118 may be installed in a garage (or other suitable location inside the structure 102). The structure 102 comprises one or more loads and/or energy storage devices 114 (e.g., portable energy systems (PES), appliances, electric hot water heaters, thermostats/detectors, boilers, electric vehicle supply equipment (EVSE), EVs, water pumps, and the like), which can be located within or outside the structure 102, and a DER controller 116, each coupled to a load center 112. Although the energy storage devices 114, the DER controller 116, and the load center 112 are depicted as being located within the structure 102, one or more of these may be located external to the structure 102.

The load center 112 is coupled to the DER 118 by an AC bus 104 and is further coupled, via a meter 152 and optionally a MID 150 (microgrid interconnect device), to a grid 124 (e.g., a commercial/utility power grid). The structure 102, the energy storage devices 114, DER controller 116, DER 118, load center 112, generation meter 154, the meter 152, and the MID 150 are part of a microgrid 180. It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122 (e.g., microinverter, power converter, power conversion units (PCUs), etc.). For example, the DER 118 may comprise a plurality of RESs 120 coupled to a plurality of power conditioners 122 in a one-to-one correspondence (or two-to-one). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one correspondence, where each pair of power conditioner 122 and a DC battery 141 may be referred to as an AC battery 130.

The power conditioners 122 invert the generated DC power from the plurality of RESs 120 and/or the DC battery 141 to AC power that is grid-compliant and couple the generated AC power to the grid 124 via the load center 112. The generated AC power may be additionally or alternatively coupled via the load center 112 to the one or more loads (e.g., EV, EVSE) and/or the energy storage devices 114. In addition, the power conditioners 122 that are coupled to the AC batteries convert AC power from the AC bus 104 to DC power for charging the AC batteries. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway that receives data (e.g., alarms, messages, operating data, performance data, and the like) from the power conditioners 122 and communicates the data and/or other information via the communications network 126 to a cloud-based computing platform 128, which can be configured to execute one or more application software, e.g., a grid connectivity control application, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application) for performing one or more of the functions described herein (e.g., the methods described herein).

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kWh) and, in some embodiments, reactive power flow (KVAR). The generation meter 154 may communicate the measured values to the DER controller 116, for example using PLC, other types of wired communications, or wireless communication. Additionally, battery charge/discharge values are received through other networking protocols from the AC battery 130 itself.

The meter 152 may be any suitable energy meter that measures the energy consumed by the microgrid 180, such as a net-metering meter, a bi-directional meter that measures energy imported from the grid 124 and well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kWh), reactive power flow (KVAR), grid frequency, and grid voltage. The meter 152 measures power flows independently of MID state, i.e., when MID is closed and DER's are connected to the grid and when MID is open and DER's are isolated from the grid.

The MID 150, which may also be referred to as an island interconnect device (IID), connects/disconnects the microgrid 180 to/from the grid 124. The MID 150 comprises a disconnect component (e.g., a, relay, a contactor, or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication), and based on the received information (inputs), the DER controller 116 determines when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly, where the disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, or the like) communicably coupled by wireless means to the communications network 126. The mobile device 142 has a CPU, support circuits, and memory, and has one or more applications (e.g., a grid connectivity control application (an application 146)) installed thereon for controlling the connectivity with the grid 124 as described herein. The mobile device 142 may run on commercially available operating systems, such as IOS, ANDROID, and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, the scenarios below, listed in order of priority, will be managed differently. Based on the desired action as entered by the user 140, the corresponding instructions are communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

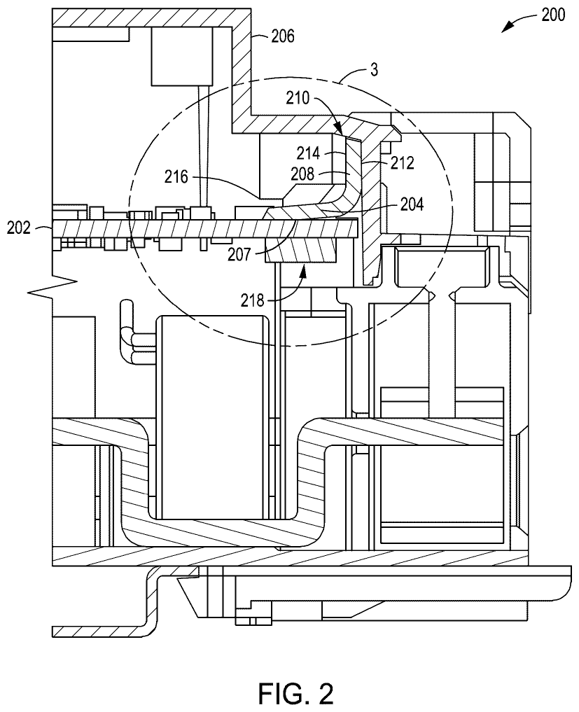

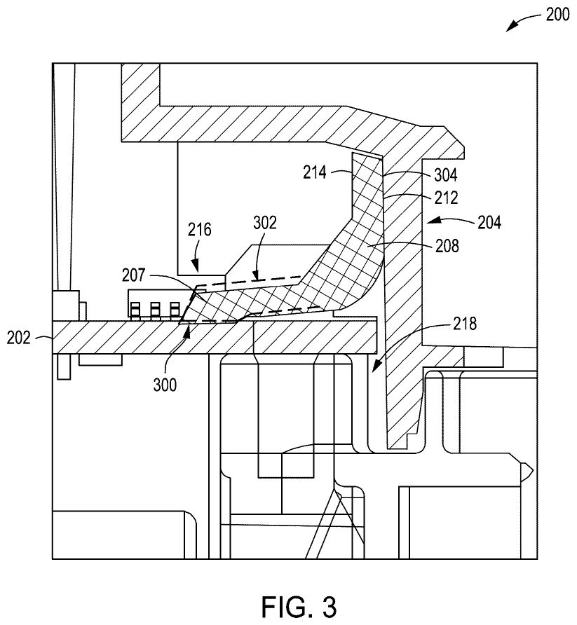

FIG. 2 is partial diagram of an enclosure configured for use with one or more components of the system for power conversion of FIG. 1 and comprising a clip configured to secure a board to the enclosure, and FIG. 3 is the indicated area of detail 3 of FIG. 2 with some parts removed for clarity and with the clip shown prior to and after installation (shown in phantom) of the board, in accordance with at least some embodiments of the present disclosure. For example, the enclosure is configured to house one or more components of the system 100. The one or more components in the energy management system can comprise at least one of photovoltaics, microinverters, storage systems, or main panels. Likewise, the board comprises electronics used for one or more components in an energy management system.

For example, in at least some embodiments, an enclosure 200 is configured to house components of the DER controller 116 (e.g., a gateway). As noted above, the DER controller 116 is configured to, inter alia, receive data (e.g., alarms, messages, operating data, performance data, and the like) from the power conditioners 122 and communicates the data and/or other information via the communications network 126 to a cloud-based computing platform 128. Accordingly, to be able to achieve such functions, the DER controller 116 comprises one or more boards 202 (PCBA shown in FIG. 2) that are secured (firmly held in place) to the enclosure 200 via one or more adaptable clips 204 (e.g., one, two, three, four, five, . . . adaptable clips). For example, in at least some embodiments, four adaptable clips (one adaptable clip shown in FIG. 2) can be operably coupled to a lid 206 of the enclosure 200. The one or more adaptable clips 204, which can be made from at least one of metal or plastic, are configured to move from an unflexed configuration 300 (FIG. 3) for receiving the board 202 to a flexed configuration 302 (shown in phantom in FIG. 3) for firmly (adequately) securing the board 202 to the enclosure 200. For example, the one or more adaptable clips 204 are configured to flex at a bottom portion 207 to accommodate various/different tolerances of the board 202 as per a product need. For example, the bottom portion 207 can be configured to flex to accommodate relatively small tolerances of the board 202 (e.g., from about −0.1 mm to about +0.1 mm) and relatively large tolerances of the board 202 (e.g., from about −1.0 mm to about +1.0 mm). In at least some embodiments, the bottom portion 207 can be configured to flex to accommodate tolerances of the board 202 from about −0.4 mm to about +0.4 mm.

The one or more adaptable clips 204 are coupled to the lid 206 of the enclosure 200 via one or more suitable coupling methods/apparatus (e.g., bonding, adhesives, screws, nuts, bolts, tapes, etc.). In at least some embodiments, the one or more adaptable clips 204 are coupled to the lid 206 of the enclosure 200 via an interference fit (press fit or friction fit) using a flexible snap 304, which can be made from metal and/or plastic, that secures the one or more adaptable clips 204 to the lid 206. For example, the one or more adaptable clips 204 can comprise an upper portion 208 that comprises the flexible snap 304 and that is configured to be received within a space 210 defined by a wall 212 and a wall 214 in the lid 206. When the upper portion 208 is inserted into the space 210, the flexible snap 304 presses or pushes against the wall 212 to facilitate coupling the upper portion 208 to the lid 206 within the space 210.

The lid 206 comprises a stopper 216 (or a ledge) that is configured to control a flexibility of the one or more adaptable clips 204, hold the board 202 firmly in place to the enclosure 200, and prevent the one or more adaptable clips 204 from over flexing and breaking when the board 202 is being connected to the enclosure 200. For example, the bottom portion 207 is configured to contact the stopper 216 to control a flexibility of the one or more adaptable clips 204, hold the board 202 firmly in place to the enclosure 200, and prevent the one or more adaptable clips 204 from over flexing and breaking when the board 202 is being connected to the enclosure 200.

To couple the board 202 to the enclosure 200, a user inserts the board 202 between the bottom portion 207 of the one or more adaptable clips 204 and a board mount 218 which causes the bottom portion 207 to move from the unflexed configuration 300 (FIG. 3) for receiving the board 202 to the flexed configuration 302 (shown in phantom in FIG. 3) for firmly (adequately) securing the board 202 to the enclosure 200.

While the foregoing is directed to embodiments of the present disclosure, other and further embodiments of the disclosure may be devised without departing from the basic scope thereof, and the scope thereof is determined by the claims that follow.

1. An apparatus for securing a board to an enclosure, comprising:
an adaptable clip operably coupled to a lid of the enclosure and configured to move from an unflexed configuration for receiving the board to a flexed configuration for securing the board to the enclosure.

2. The apparatus of claim 1, wherein the adaptable clip is coupled to the lid of the enclosure via an interference fit using a flexible snap that holds the adaptable clip to the lid.

3. The apparatus of claim 1, wherein the adaptable clip is configured to flex to accommodate tolerances of the board from about −0.4 mm to about +0.4 mm.

4. The apparatus of claim 1, wherein the lid comprises a stopper that is configured to control a flexibility of the adaptable clip, hold the board firmly in place to the enclosure, and prevent the adaptable clip from over flexing and breaking when the board is being connected to the enclosure.

5. The apparatus of claim 1, wherein the adaptable clip is made from at least one of metal or plastic.

6. The apparatus of claim 1, wherein the board comprises electronics used for one or more components in an energy management system.

7. The apparatus of claim 6, wherein the one or more components in the energy management system comprises at least one of photovoltaics, microinverters, storage systems, or main panels.

8. The apparatus of claim 1, wherein the board is at least one of a printed circuit board or printed circuit board assembly.
